(19) United States
(12) Patent Application Publication
(10) Pub. No.: US 2025/0250161 A1
(43) Pub. Date: Aug. 7, 2025

(54) CANTILEVER BEAM BASED PRESSURE SENSOR SYSTEMS AND DEVICES MEHTHODS OF USE THEREOF

(71) Applicant: UNIVERSITY OF NORTH TEXAS, Denton, TX (US)

(72) Inventors: Haifeng Zhang, Denton, TX (US); Sreejith Vattaparambil Sreedharan, Denton, TX (US)

(21) Appl. No.: 19/046,770

(22) Filed: Feb. 6, 2025

Related U.S. Application Data
(60) Provisional application No. 63/550,791, filed on Feb. 7, 2024.

(51) Int. Cl. B81B 7/00; G01L 9/00

(52) U.S. Cl. CPC B81B 7/0019; G01L 9/0016; G01L 9/0025; B81B 2201/0264; B81B 2201/0271; B81B 2201/0278; B81B 2203/0118; B81B 2203/0127

(57) ABSTRACT

The present disclosure relates to systems, methods, devices for cantilever based pressuring monitoring, and the like. The systems and devices of the present disclosure can be used in caustic or harsh environments. Continuous pressure monitoring using the described devices can enable real-time adjustments for precise process control, contributing to improved efficiency and product quality.

### CROSS-REFERENCE TO RELATED APPLICATIONS

This application claims the benefit of U.S. Provisional Application entitled “CANTILEVER BEAM BASED PRESSURE SENSOR DEVICE” and having Ser. No. 63/550,791, filed on Feb. 7, 2024, which is incorporated herein by reference in its entirety.

### STATEMENT ON FUNDING PROVIDED BY THE U.S. GOVERNMENT

This invention was made with government support under award number DE-AR0001691 awarded by Department of Energy. The government has certain rights in the invention.

### BACKGROUND

Pressure monitoring in industry is utilized for ensuring safety, optimizing processes, and complying with regulations. It can help to prevent overpressure situations that could lead to accidents or equipment failure, safeguarding both personnel and assets. It also helps maintain equipment integrity by allowing for proactive maintenance and reducing downtime. Pressure monitoring ensures compliance with regulatory standards, avoiding legal issues and fines. Additionally, it supports energy efficiency, environmental protection, and cost savings by preventing leaks, optimizing energy consumption, and providing valuable data for analysis and optimization.

### SUMMARY

The present disclosure relates to systems, methods, devices for cantilever based pressuring monitoring, and the like.

The present disclosure provides for a cantilever-based sensor device, comprising: a flexible metal diaphragm that deforms in the presence of pressure against a first surface of the flexible metal diaphragm; a housing that is at least partially enclosed using the flexible metal diaphragm over an opening of the housing; a sensor component comprising a cantilever-based resonant sensor; a column that connects between the flexible metal diaphragm and the resonant sensor, wherein the column connects to a second surface of the flexible metal diaphragm, wherein the second surface is on the opposite side of the first surface of the flexible metal diaphragm, wherein the column applies a tip force at a position of the cantilever based resonant sensor in an instance in which the flexible metal diaphragm deforms, and the cantilever-based resonant sensor correlates to a pressure value based at least in part on a frequency shift in a resonant frequency of the cantilever based resonant sensor that results from the tip force.

The present disclosure provides for a system for measuring pressure, comprising: a cantilever-based sensor device within a structure of a processing system, wherein a first surface of a flexible metal diaphragm of the cantilever-based sensor device is in fluidic communication with a fluid in an inside region of the structure, wherein the fluid is a gas, a liquid, or a mixture of a gas and a liquid, wherein the flexible metal diaphragm is configured to deform to a degree based on a pressure against a first surface of the flexible metal diaphragm, wherein the pressure is from the fluid, wherein the cantilever-based sensor device comprises: a sensor component comprising a cantilever-based resonant sensor; a column that connects between the flexible metal diaphragm and the resonant sensor, wherein the column connects to a second surface of the flexible metal diaphragm, wherein the second surface is on the opposite side of the first surface of the flexible metal diaphragm, wherein the column applies a tip force at a position of the cantilever based resonant sensor in an instance in which the flexible metal diaphragm deforms based on the pressure against the first surface, wherein a frequency shift in a resonant frequency of the cantilever based resonant sensor that results from the tip force produces a signal; and a computing device is communicatively coupled with the cantilever-based sensor device, wherein the computing device receives the signal and is configured to compute a pressure value, wherein the computing device is communicatively coupled with the processing system, wherein the processing system is configured to process a pressure-based response based on the pressure value.

The present disclosure provides for a method for measuring one or more parameters in a process, comprising: flowing a fluid in a structure in a processing system; and measuring a pressure against a first surface of a flexible metal diaphragm of a cantilever-based sensor device within the structure of the processing system, wherein the flexible metal diaphragm is configured to deform to a degree based on a pressure against a first surface of the flexible metal diaphragm, wherein a first surface of a flexible metal diaphragm of the cantilever-based sensor device is in fluidic communication with a fluid in an inside region of the structure, wherein the fluid is a gas, a liquid, or a mixture of a gas and a liquid, wherein the pressure is from the fluid; wherein the cantilever-based sensor device comprises: a sensor component comprising a cantilever-based resonant sensor; a column that connects between the flexible metal diaphragm and the resonant sensor, wherein the column connects to a second surface of the flexible metal diaphragm, wherein the second surface is on the opposite side of the first surface of the flexible metal diaphragm, wherein the column applies a tip force at a position of the cantilever based resonant sensor in an instance in which the flexible metal diaphragm deforms based on the pressure against the first surface, wherein a frequency shift in a resonant frequency of the cantilever based resonant sensor that results from the tip force produces a signal that correlates to a pressure value. In an aspect, the method also includes measuring the temperature in the fluid.

### BRIEF DESCRIPTION OF THE DRAWINGS

Aspects of the present disclosure can be better understood with reference to the following drawings. It is noted that the elements in the drawings are not necessarily to scale, with emphasis instead being placed upon clearly illustrating the principles of the embodiments. In the drawings, like reference numerals designate like or corresponding, but not necessarily the same, elements throughout the several views.

FIG. 1 illustrates an example industrial system that includes a cantilever based pressuring monitoring device, according to various embodiments described herein.

FIG. 2 illustrates an example of a cantilever based pressuring monitoring device, according to various embodiments described herein.

FIG. 3 illustrates another example of a cantilever based pressuring monitoring device, according to various embodiments described herein.

FIG. 4 is a drawing depicting a computing device for one or more of the components of the industrial system that includes the cantilever based pressuring monitoring device, according to various embodiments described herein.

### DETAILED DESCRIPTION

The present disclosure relates to systems, methods, and devices for cantilever based pressuring monitoring.

This disclosure is not limited to particular embodiments described, and as such may, of course, vary. The terminology used herein serves the purpose of describing particular embodiments only, and is not intended to be limiting, since the scope of the present disclosure will be limited only by the appended claims.

Where a range of values is provided, each intervening value, to the tenth of the unit of the lower limit unless the context clearly dictates otherwise, between the upper and lower limit of that range and any other stated or intervening value in that stated range, is encompassed within the disclosure. The upper and lower limits of these smaller ranges may independently be included in the smaller ranges and are also encompassed within the disclosure, subject to any specifically excluded limit in the stated range. Where the stated range includes one or both of the limits, ranges excluding either or both of those included limits are also included in the disclosure.

Embodiments of the present disclosure will employ, unless otherwise indicated, techniques of mechanical engineering, and the like, which are within the skill of the art. Such techniques are explained fully in the literature.

The following examples are put forth so as to provide those of ordinary skill in the art with a complete disclosure and description of how to perform the methods and use the compositions and compounds disclosed and claimed herein. Efforts have been made to ensure accuracy with respect to numbers (e.g., amounts, temperature, etc.), but some errors and deviations should be accounted for. Unless indicated otherwise, parts are parts by weight, temperature is in ° C., and pressure is at or near atmospheric. Standard temperature and pressure are defined as 20° C. and 1 atmosphere.

Before the embodiments of the present disclosure are described in detail, it is to be understood that, unless otherwise indicated, the present disclosure is not limited to particular materials, reagents, reaction materials, manufacturing processes, dimensions, frequency ranges, applications, or the like, as such can vary. It is also to be understood that the terminology used herein is for purposes of describing particular embodiments only, and is not intended to be limiting. It is also possible in the present disclosure that steps can be executed in different sequence, where this is logically possible. It is also possible that the embodiments of the present disclosure can be applied to additional embodiments involving measurements beyond the examples described herein, which are not intended to be limiting. It is furthermore possible that the embodiments of the present disclosure can be combined or integrated with other measurement techniques beyond the examples described herein, which are not intended to be limiting.

It should be noted that, as used in the specification and the appended claims, the singular forms “a,” “an,” and “the” include plural referents unless the context clearly dictates otherwise. Thus, for example, reference to “a support” includes a plurality of supports. In this specification and in the claims that follow, reference will be made to a number of terms that shall be defined to have the following meanings unless a contrary intention is apparent.

### Discussion:

The present disclosure relates to systems, methods, and devices for cantilever based pressuring monitoring. While pressure monitoring is performed, temperature monitoring can also be performed in some embodiments. The described mechanisms can be used in caustic or harsh environments. Continuous pressure monitoring using the described devices can enable real-time adjustments for precise process control, contributing to improved efficiency and product quality. By detecting potential issues early according to predetermined pressure and/or temperature thresholds measured by the device, the overall system can generate control output instructions and/or in real-time (e.g., less than a centisecond) or near-real-time (e.g., less than a dekasecond) for adjustment of facility control parameters (e.g., pressure, temperature, flow rate, etc.) of a processing system such as a boiler systems, a power generation system, and other industrial machines controls. Traditional techniques can be impractical, inefficient, and slow. Harsh environment technologies present a number of challenges. The present disclosure describes mechanisms that monitor pressure and temperature in harsh environments.

The mechanisms described can enable pressure monitoring in harsh environments for safety, reliability, and operational resilience. In these challenging conditions, where factors like extreme temperatures, corrosive substances, and high vibration levels are prevalent, pressure monitoring becomes crucial to prevent accidents and equipment failures. The continuous monitoring of pressure ensures that industrial machinery operates within safe limits, allowing for early detection of potential issues and facilitating proactive maintenance notifications and control signals. This approach not only enhances equipment reliability but also contributes to process optimization in challenging settings. The mechanisms described enable compliance with stringent safety and environmental regulations, prevention of catastrophic failures, and the ability to remotely monitor conditions further underscore the significance of pressure monitoring in harsh environments. The mechanisms described in the present disclosure include a cantilever beam-based piezoelectric pressure sensor that addresses the challenges of high-temperature (e.g., 700° to 800° C., or another threshold range of temperatures) and other harsh environments.

In an aspect, the present disclosure provides for cantilever-based sensor devices. The cantilever-based sensor device can include a flexible metal diaphragm, a housing, a sensor component, and a column. In an embodiment, the flexible metal diaphragm can deform in the presence of pressure against a first surface of the flexible metal diaphragm. The degree of deformation can be correlated to a pressure value. The housing is at least partially enclosed using the flexible metal diaphragm over an opening of the housing. The housing can include a vent as well. The housing can include a sensor component within the housing, where the sensor component, can include a cantilever-based resonant sensor (e.g., a tuning fork resonator, SAW (Surface Acoustic Wave) resonator or BAW (Bulk Acoustic Wave) resonator). The column can connect the flexible metal diaphragm and the resonant sensor. In an aspect, the column can be attached to a second side of the flexible metal diaphragm, or the column can be attached to an extension component. The second surface is on the opposite side of the first surface (e.g., exposed to the fluid causing the pressure) of the flexible metal diaphragm. The column can apply a tip force at a position (e.g., distal end) of the cantilever based resonant sensor in an instance in which the flexible metal diaphragm deforms. The cantilever-based resonant sensor correlates to a pressure value based at least in part on a frequency shift in a resonant frequency of the cantilever based resonant sensor that results from the tip force.

In an embodiment the cantilever-based sensor device includes an extension component that extends into an interior area at least partially enclosed or surrounded by the housing. The cantilever based resonant sensor is attached to the extension component and is in contact with or attached to the column.

In an aspect, the cantilever-based sensor device can include a spacing ring component that is between the flexible metal diaphragm and the extension component, providing space between the extension component and the flexible metal diaphragm.

In an embodiment, the cantilever-based sensor device can include a temperature-sensing component within the housing, where the temperature-sensing component can optionally be attached to the extension component.

In an aspect, the flexible metal diaphragm can have one or more designs. In an embodiment, the flexible metal diaphragm can have a flat shape that fits over a plane formed by the opening of the housing, while in another embodiment, the flexible metal diaphragm can have a shape that includes a flexing portion and a sealing portion, where the flexing portion enables flexion while the sealing portion fits onto the housing.

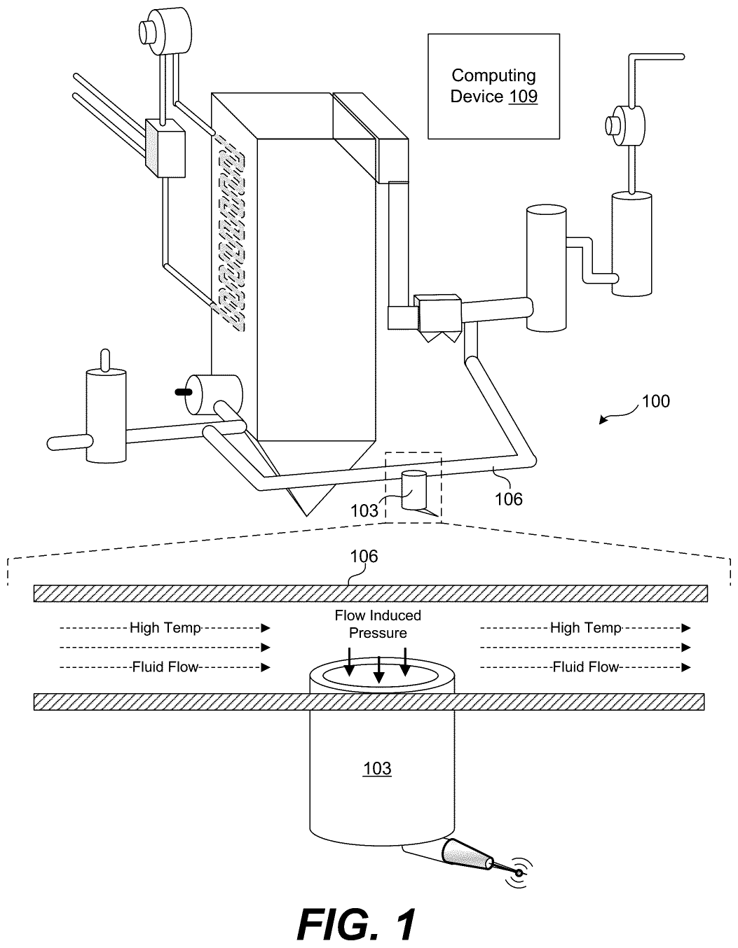

Additional details and features of the cantilever-based sensor device are provided in the discussion of FIGS. 1-4, where those details and features can be applied to the foregoing description.

In an aspect, the present disclosure provides for a system for measuring pressure. In an aspect the system can include the cantilever-based sensor device and the computing device. The cantilever-based sensor device can within a structure (e.g., pipe, tank, valve, and the like) of a processing system. The first surface of the flexible metal diaphragm of the cantilever-based sensor device is in fluidic communication with a fluid (e.g., gas, a liquid, or a mixture of a gas and a liquid (e.g., steam)) in an inside region of the structure. The flexible metal diaphragm is configured to deform to a degree based on a pressure against a first surface of the flexible metal diaphragm, where the pressure is from the fluid.

In an aspect, the column applies a tip force at a position of the cantilever based resonant sensor in an instance in which the flexible metal diaphragm deforms based on the pressure against the first surface. A signal can be produced based on a frequency shift in a resonant frequency of the cantilever based resonant sensor that results from the tip force.

The computing device is communicatively coupled with the cantilever-based sensor device. The computing device receives the signal and is configured to compute a pressure value. The computing device is communicatively coupled with the processing system. Based on the information received from the computing device, the processing system is configured to process a pressure-based response based on the pressure value.

When the cantilever-based sensor device includes a temperature-sensing component, the computing device receives a temperature signal from the cantilever-based sensor device and determines a temperature value. The processing system is configured to process a temperature-based response based on the temperature value. In addition, the processing system is configured to process the temperature-based response to the temperature value and the pressure-based response to the pressure value to produce a parameter-based response. For example, if the pressure and/or temperature are not within certain predetermined ranges, then the processing system can take appropriate action (e.g . . . , turn off the system, adjust fluid flow, adjust appropriate parameters to ensure the processing system is functioning as desired).

In an aspect, the present disclosure provides for methods of measuring one or more parameters, such as pressure and temperature, in a process. The method can include flowing a fluid in a structure in a processing system and measuring a pressure against the first surface of the flexible metal diaphragm of the cantilever-based sensor device within the structure (e.g., pipe, valve, tank) of a processing system. As described herein, the column of the cantilever-based sensor device applies a tip force at a position of the cantilever based resonant sensor in an instance in which the flexible metal diaphragm deforms based on the pressure against the first surface. The tip force produces a frequency shift in a resonant frequency of the cantilever based resonant sensor which produces a signal that correlates to a pressure value. In an embodiment where a parameter is temperature, the method includes measuring a temperature using a temperature-sensing component, where the cantilever-based sensor device comprises the temperature-sensing component. In an aspect, the method includes communicating the signal and the temperature to a computing device. The computing device is configured to compute the pressure value. The computing device is communicatively coupled with the processing system. The processing system is configured to process a pressure-based response to the pressure value. In addition, the processing system can be configured to process a temperature-based response to the temperature value.

Now having described various features of the present disclosure, additional features will be discussed in reference to FIGS. 1-4. With reference to FIG. 1, shown is an example industrial system (or processing system) 100 that includes a cantilever-based pressure sensor device 103. As shown in FIG. 1, the cantilever-based pressure sensor device 103 can be installed in a pipe 106 of the industrial system 100 that carries high temperature fluid such as gasses, liquids, other fluids, or any combination thereof. The industrial system 100 can include a boiler system or another type of industrial machine, device, system, or process. The pipe 106 can refer to a recirculation pipe or any other type of pipe. The cantilever-based pressure sensor device 103 can be installed within a pipe as shown, but additionally or alternatively can be installed within another industrial structure such as a tank, housing, valve, tub, conduit, reservoir, and so on.

The cantilever-based pressure sensor device 103 can employ a resonator (e.g., piezoelectric resonator) such as tuning fork resonators, SAW (Surface Acoustic Wave) resonator or BAW (Bulk Acoustic Wave) resonator, fashioned as a narrow and elongated cantilever beam. This beam is intricately linked to a diaphragm (e.g., stainless-steel) through a stainless-steel column. Under pressure, the diaphragm undergoes deformation, generating a tip force at the cantilever beam's end. This force induces a frequency shift in the cantilever-based pressure sensor device 103. Accurate pressure readings are then obtained by measuring this frequency shift. The design enables the cantilever-based pressure sensor device 103 to operate reliably in conditions characterized by elevated temperatures and harsh environmental factors, making it a valuable tool for applications in demanding industrial settings.

The pipe 106 is shown connecting from a pipe on the fuel and air supply combustion side of the industrial system 100 to a pipe on the exhaust side of the industrial system 100. The cantilever-based pressure sensor device 103 is connected to the pipe 106 such that one side or surface of the device is within or exposed to an interior of the hot pipe 106 and another side or surface of the device is outside of the interior of the pipe 106. The cantilever-based pressure sensor device 103 can detect pressure and optionally temperature within the pipe or other structure continuously or periodically. The cantilever-based pressure sensor device 103 can transmit this environmental data to a control device and/or a warning system of the industrial system 100. This can be performed using a wired or wireless network that connects the cantilever-based pressure sensor device 103 to one or more computing devices 109.

The computing devices 109 can include one or more computing devices that include a processor, a memory, and/or a network interface. The computing devices 109 can include personal computers, desktop computers, laptop computers, mobile phones, tablets, gaming consoles, wearable devices, smart televisions, smart devices, server devices, controller devices, and other devices. The cantilever-based pressure sensor device 103 can include its own local computing device 109 or the cantilever-based pressure sensor device 103 can be c communicatively coupled to the computer device 109.

A computing device 109 can be configured to perform computations on behalf of other computing devices 109 or applications. As another example, such computing devices 109 can host and/or provide content to other computing devices in response to requests for content. Moreover, the computing device 109 can refer to a plurality of computing devices 109 that can be arranged in one or more server banks or computer banks or other arrangements. Such computing devices 109 can be located in a single installation or can be distributed among many different geographical locations. For example, the computing device 109 can include a plurality of computing devices 109 that together can include a hosted computing resource, a grid computing resource or any other distributed computing arrangement. In some cases, the computing device 109 can correspond to an elastic computing resource where the allotted capacity of processing, network, storage, or other computing-related resources can vary over time.

The network used by the cantilever-based pressure sensor device 103 and the computing devices 109 can include wide area networks (WANs), local area networks (LANs), personal area networks (PANs), or a combination thereof. These networks can include wired or wireless components or a combination thereof. Wired networks can include Ethernet networks, cable networks, fiber optic networks, and telephone networks such as dial-up, digital subscriber line (DSL), and integrated services digital network (ISDN) networks. Wireless networks can include cellular networks, satellite networks, Institute of Electrical and Electronic Engineers (IEEE) 802.11 wireless networks (i.e., WI-FI®), BLUETOOTH® networks, microwave transmission networks, as well as other networks relying on radio broadcasts. The network can also include a combination of two or more networks. Examples of networks can include the Internet, intranets, extranets, virtual private networks (VPNs), and similar networks.

High temperature fluid flow is shown in a particular direction, but can potentially be in either direction and can change direction during operation in the various embodiments of the disclosure. In addition, in some examples where the cantilever-based pressure sensor device 103 is monitoring another structure such as an open container holding fluids, or a sealed housing holding pressurized fluids, there may be no flow or minimal flow. Nevertheless, pressures can be applied to and monitored using the cantilever-based pressure sensor device 103.

A high temperature antenna can enable the cantilever-based pressure sensor device 103 to communicate with an interrogator or client device 109 that includes software for visualization and display of temperature and pressure detected using the cantilever-based pressure sensor device 103. The antenna can include components capable of wireless communications over one or more local area networks or wide area networks. Wireless transmission components can include devices capable of generating or communicating over cellular networks, satellite networks, IEEE 802.11 wireless networks WI-FI®, BLUETOOTH® networks, Zigbee® networks, microwave transmission networks, as well as other networks relying on radio broadcasts. For example, the wireless transmission components can include wireless chips such as Xbee® 3 or Xbee-Pro®.

The cantilever-based pressure sensor device 103 can communicate with a parameter monitoring service of the industrial system 100. This can include a display that shows a readout in a control room of a facility, such as a power generation facility, an industrial facility, a medical facility, and so on depending on the application of the cantilever-based pressure sensor device 103. The parameter monitoring service can also be used to control and adjust parameters of the industrial system 100 in response to temperatures and pressures detected using the cantilever-based pressure sensor device 103.

One or more of the client devices 109 can provide a parameter monitoring service that is located locally or remotely. The parameter monitoring service can generate and output parameters such as, for example, temperature and pressure detected using the cantilever-based pressure sensor device 103. The parameter monitoring service can include a display and can show the parameter outputs as well as a history of the temperature and pressure on the display. The historical datapoints can be graphed to show a change of the parameters over time, calculate an average, median, or moving average over a specified time chunk and so on. The parameter monitoring service can also provide these parameter outputs to control systems that provide notifications to administrators, engineers, and other users to alert them to operating conditions. The user interface and/or the notification can indicate an action to take in response to the parameters, such as an indication to service the battery, power generation, boiler ignition system, medical, or other electrode device. In some examples, the control systems that receive parameters from the parameter monitoring service can make automatic adjustments such as stopping or modifying a boiler system ignition, valve, fane, or otherwise affecting a gas flow through the recirculation pipe.

The parameter monitoring service can include instructions that map the pressures and temperatures received from the cantilever-based pressure sensor device 103 to the output parameters. The output parameters can also be mapped to specified actions such as transmitting a notification or transmitting a subset of the parameters as a notification or instructions to provide rectifying or corrective action.

The parameter monitoring service can be executed using one or more computing devices that are in wired and/or wireless communications with the cantilever-based pressure sensor device 103. For example, the parameter monitoring service can include a cloud-based service that is accessible over a public wide area network such as the Internet. The parameter monitoring service can include a service that is hosted privately and is accessible over a private wide area network, or a local area network.

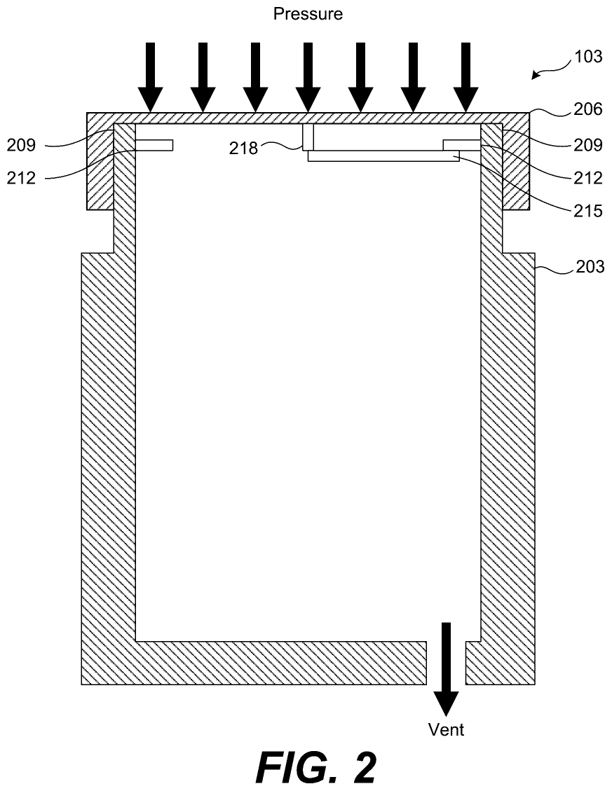

FIG. 2 shows one example of a cantilever-based pressure sensor device 103. The cantilever-based pressure sensor device 103 can include a housing 203, a diaphragm 206, a spacing ring 209, an extension component 212, a sensor component 215, a column 218, and other components such as a wired or wireless network interface and corresponding components.

The overall assembly of the housing 203, diaphragm 206, and other components of the cantilever-based pressure sensor device 103 can be fluid-tight with respect to the fluid that applies pressure to the diaphragm 206. For example, the cantilever-based pressure sensor device 103 can be gas-tight if the fluid is a gas, or liquid-tight if the fluid is a liquid and so on. The terms gas-tight and liquid-tight can indicate that the exterior gasses exterior to the cantilever-based pressure sensor device 103 cannot enter the interior formed by the housing 203, diaphragm 206, and other components of the cantilever-based pressure sensor device 103.

The housing 203 can be formed using a metal such as stainless steel, titanium, tantalum, or another corrosion-resistant metal, or another corrosion-resistant rigid material. This housing 203 can provide a rigid structure to which the other components of the cantilever-based pressure sensor device 103 can attach. The housing 203 can be formed with a predetermined thickness that is selected so that the material of the housing 203 can withstand a predetermined pressure or range of pressures. Generally, the housing 203 can be withstand the predetermined pressure or range of pressures without flexing or deforming.

The housing 203 can be fully-enclosed housing or partially enclosed in various embodiments. In some examples, the diaphragm-side of the housing 203 can be within a pipe, a container, a boiler, or another industrial component, while a mid-section of the housing 203 extends through and seals to a wall of the industrial component. In that example, the housing 203 can be a rigid structure that is partially enclosed on the side that is inside the industrial component, while having an opening on the outside.

Generally, the housing 203 can refer to a structure with at least one open end, and the diaphragm 206 can be designed to have a shape and size to cover and seal an open end of the housing 203. The housing 203 can be a substantially cylindrical shape with one open end and one closed end, or the exterior can be an arbitrary shape while the interior is a cylindrical shape with one or both ends open. In other examples, the housing 203 can be a rectangular prism or another shape with respect to at least one of its interior and exterior. The housing 203 can also include a vent. The vent can enable the pressure against the diaphragm 206 to deform the diaphragm 206, by enabling the contents of the housing 203 to escape rather than increasing internal pressure that resists deformation.

The diaphragm 206 can be formed using a metal such as stainless steel, titanium, tantalum, or another corrosion-resistant metal, or another corrosion-resistant rigid material. The diaphragm 206 can provide a barrier between the caustic environment and an interior of the housing 203, when the diaphragm 206 is connected over an open end of the housing 203. The diaphragm 206 can be designed to have a selected thickness that enables the metal or other material of the diaphragm 206 to temporarily flex or deform while maintaining structural integrity (e.g., resisting permanent bends and breaks) within the predetermined range of pressures that the cantilever-based pressure sensor device 103 is designed to detect. The flexion of the diaphragm 206 can respond to pressure changes within an industrial structure where the cantilever-based pressure sensor device 103 is placed.

The diaphragm 206 is shown having a shape that includes a flexing portion and a sealing portion. The flexing portion enables flexion while the sealing portion can have an inside shape that fits over an outside shape of the open end of the housing 203, providing the environmentally-tight or fluid-tight seal. However, in other some examples, the diaphragm 206 can be formed in a shape that is limited to the flexing portion, and/or is a flat shape that fits over a plane formed by the open end of the housing 203, and forms a seal when a sealing component is fitted over the diaphragm 206, such that the diaphragm 206 is sandwiched between the housing 203 and the sealing component. In that example, the sealing component can have an inside peripheral shape (e.g., cylindrical, polygonal, rectangular, or arbitrary shape) that fits over an outside peripheral shape (e.g., cylindrical, rectangular, polygonal, or arbitrary shape) that extends to the open end of the housing 203; and the sealing component can have an further have an interior ridge that holds the diaphragm 206 down against the plane formed by the open end of the housing 203.

The spacing ring 209 can be formed using a metal such as stainless steel, titanium, tantalum, or another corrosion-resistant metal, or another corrosion-resistant rigid material. The spacing ring 209 can be formed using a non-corrosion-resistant material in an instance in which the fitment of the diaphragm 206 and the housing 203 are tight enough to prevent intrusion of external fluids without the aid of the spacing ring 209. The spacing ring 209 can be provided so that the diaphragm 206 can flex without affecting or impacting the extension component 212 that holds the sensor component 215. In some examples, no spacing ring is used, and the shape formed by the spacing ring in integrated into at least one of the diaphragm 206 or the extension component 212.

The extension component 212 can be formed using any rigid material including metals, plastics, carbon-based materials, semiconductor-based materials, and others. The extension component 212 can also be formed using a metal such as stainless steel, titanium, tantalum, or another corrosion-resistant metal, or another corrosion-resistant rigid material. The extension component 212 can be formed as a ring that has a narrower internal diameter (or rectangle, or other internal shape) defining an opening parallel to the open end of the housing adjacent to the diaphragm 206.

The sensor component 215 can include a resonator component such as a piezoelectric (or other) tuning fork resonator, or other resonator component. The sensor component 215 can include a microelectromechanical systems (MEMS) device or another kind of device. The resonator component can be designed as an elongated cantilever beam. This beam is linked to a diaphragm 206 through the column 218. The column 218 can be formed using a metal such as stainless steel, titanium, tantalum, or another corrosion-resistant metal, or another corrosion-resistant rigid material. The column 218 can refer to any rigid columnar or elongate component that attaches or makes contact between the diaphragm 206 and the “pressure” sensor component 215.

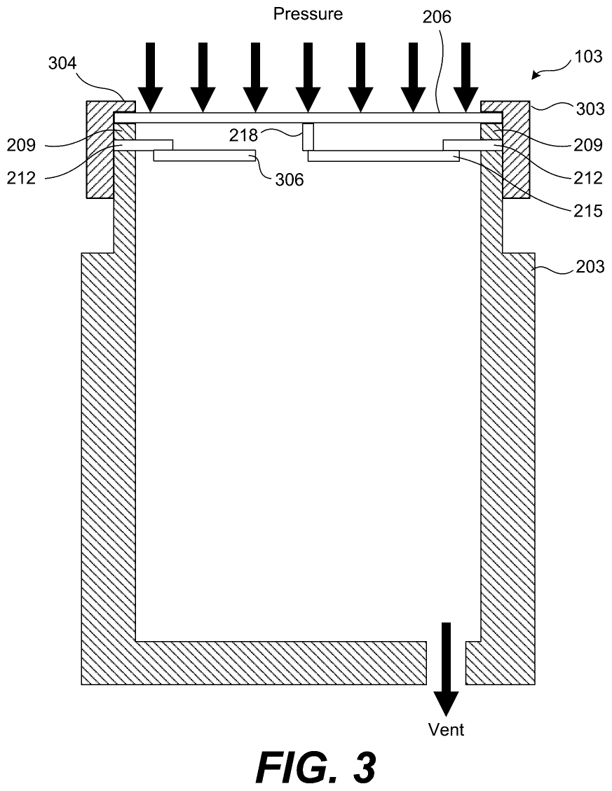

Under pressure, the diaphragm 206 undergoes deformation or flexion, generating a tip force at the cantilever beam's end. This force induces a frequency shift in the sensor component 215 that can be utilized by the overall cantilever-based pressure sensor device 103 by measuring the frequency shift to identify accurate pressure readings. In some examples, a computing device 109 exterior to the cantilever-based pressure sensor device 103 can use frequency data received from the cantilever-based pressure sensor device 103 to measure the frequency shift to identify accurate pressure readings. The sensor component 215 can be designed to detect temperature variations using the resonator component's changes in frequency. For example, the sensor component 215 can include a piezoelectric or other material on its surface and/or interior, and the mechanical and/or electrical properties of this material can change as the pressure (and temperature, see FIG. 3 for additional information on temperature connections using a temperature sensor) changes under flexion of the diaphragm 206, thereby altering the resonant frequency.

FIG. 3 shows one example of a cantilever-based pressure sensor device 103. The cantilever-based pressure sensor device 103 can include a housing 203, a diaphragm 206, a spacing ring 209, an extension component 212, a sensor component 215, a column 218, a sealing component 303, a second (e.g., temperature-measurement-enabling) sensor component 306 and other components such as a wired or wireless network interface and corresponding components. While much of the cantilever-based pressure sensor device 103 of FIG. 3 can be described in a manner similar to that of FIG. 2 as discussed, this example shows how a second sensor component 306 can be used along with the sensor component 215 to enable temperature readings.

By comparison with the single diaphragm 206 of FIG. 2, which includes a flexing or deforming portion and a sealing portion, the diaphragm 206 can be formed in a shape that is limited to the flexing portion. For example, the diaphragm 206 in FIG. 3 can include a flat or planar component with a shape that aligns and sits on a plane formed by an open end of the housing 203, and forms a seal over the housing 203, in an instance in which the sealing component 303 is fitted over the diaphragm 206. As can be seen, the diaphragm 206 can be sandwiched between the housing 203 and the sealing component 303.

The sealing component can have an inside peripheral shape (e.g., cylindrical, rectangular, or arbitrary shape) that fits over an outside peripheral shape (e.g., cylindrical, polygonal, rectangular, or arbitrary shape) that extends to the open end of the housing 203. The sealing component 303 can have a further have a ridge 304 that holds the diaphragm 206 down against the plane formed by the open end of the housing 203. It is noted that this diaphragm 206 can be used with or without the additional temperature sensing component 306.

In this example, the extension component 212 can hold both a “first” sensor component 215, which can be referred to as a pressure-sensing component 215 since it is utilized at least partially to identify pressure; as well as a “second” sensor component 306, which can be referred to as a temperature-sensing component 306 since it is utilized at least partially to identify temperature in conjunction with the pressure-sensing component 215. While shown in a particular orientation connected directly opposite to the pressure-sensing component 215, the temperature-sensing component 306 can be placed parallel to the pressure-sensing component 215 or at any other angle and position extending from and attached to the extension component 212 or “platform ring.”

By contrast with the pressure-sensing component 215, the temperature-sensing component 306 does not make contact with the column 218 and does not directly detect the flexion of the diaphragm 206. However, the temperature-sensing component 306 can also include a piezoelectric MEMS resonator component such as a tuning fork resonator component. The resonator component can be designed as an elongated cantilever beam. However, the beam is unlinked to the diaphragm 206 and does not touch the column 218. The temperature-sensing component 306 can be designed to detect temperature variations using the resonator component's changes in frequency. For example, the temperature-sensing component 306 can include a temperature-dependent piezoelectric or other material on its surface and/or interior, and the mechanical and/or electrical properties of this material can change as the temperature changes, thereby altering the resonant frequency.

Since the distance from the diaphragm 206 can be small (e.g. 5 mm or another predetermined distance), the temperature variations can be related to the temperatures outside of the sensor device assembly and housing 203. The distance can be selected to be minimal or minimized based on the deflection of the diaphragm when subjected to pressure. For example, the selected distance ensures the deflected diaphragm does not make contact with either sensor element 215 or 306.

The temperature-sensing component 306 can actually be sensing the interior temperatures. In some examples, the temperature variations can be used as further input to calibrate and more accurately interpret the resonant frequencies of the pressure-sensing component 215, resulting in more accurate pressure readings. The temperature readings identified using the resonant frequencies of the temperature-sensing component 306 can be pre-calibrated to represent external or internal temperatures in various examples, and in either case can be utilized as inputs to identify more accurate pressure readings.

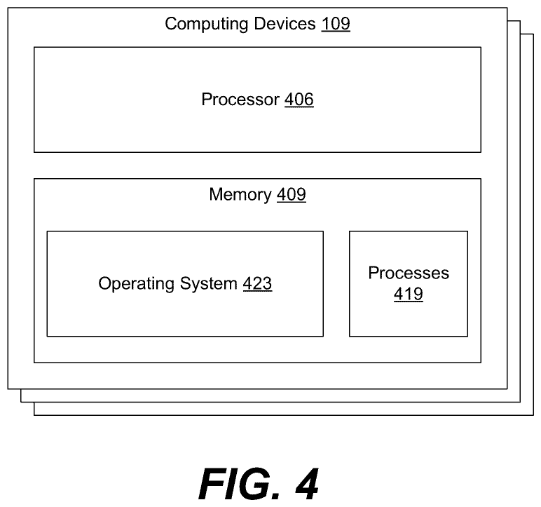

FIG. 4 depicts a schematic block diagram of one example of one or more computing devices 109 for the components of the networked environment of FIG. 1, which can include the cantilever-based pressure sensor device 103 as well as the computing device 109 shown external to the cantilever-based pressure sensor device 103 in FIG. 1. A computing device 109 can have one or more processors 406. The computing device 109 can also have a memory 409.

The processor 406 can represent any circuit or combination of circuits that can execute one or more machine-readable instructions stored in the memory 409 that make up a computer program or process and store the results of the execution of the machine-readable instructions in the memory 409. In some implementations, the processor 406 may be configured to perform one or more machine-readable instructions in parallel or out of order. This could be done if the processor 406 includes multiple processor cores and/or additional circuitry that supports simultaneous multithreading (SMT). Examples of a processor 406 can include a central processing unit (CPU), a graphics processing unit (GPU), a field-programmable gate array (FPGA), application specific integrated circuits (ASICs), etc.

The memory 409 can include both volatile and nonvolatile memory and data storage components. Volatile components are those that do not retain data values upon loss of power. Nonvolatile components are those that retain data upon a loss of power. Thus, the memory 409 can include random access memory (RAM), read-only memory (ROM), hard disk drives, solid-state drives, USB flash drives, memory cards accessed via a memory card reader, floppy disks accessed via an associated floppy disk drive, optical discs accessed via an optical disc drive, magnetic tapes accessed via an appropriate tape drive, or other memory components, or a combination of any two or more of these memory components. In addition, the RAM can include static random access memory (SRAM), dynamic random access memory (DRAM), or magnetic random access memory (MRAM) and other such devices. The ROM can include a programmable read-only memory (PROM), an erasable programmable read-only memory (EPROM), an electrically erasable programmable read-only memory (EEPROM), or other like memory device. Various types of data and machine-readable instructions may be stored in the memory 409. For example, one or more processes 419 may be stored in the memory 409. In some implementations, an operating system 423 may also be stored in the memory 409.

A process 419 can represent a collection of machine-readable instructions stored in the memory 409 that, when executed by the processor 406 of the computing device 109, cause the computing device 109 to perform one or more tasks. A process 419 can represent a program, a sub-routine or sub-component of a program, a library used by one or more programs, etc. When a process requests access to a hardware or software resource for which it lacks permission to interact with, the process 419 can generate an interrupt and provide or send the interrupt to the operating system 423.

The operating system 423 can include any system software that manages the operation of computer hardware and software resources of the computing device 109. The operating system 423 can also provide various services or functions to computer programs, such as processes 419, that are executed by the computing device 109. Accordingly, the operating system 423 may schedule the operation of tasks or processes 419 by the processor 406, act as an intermediary between processes 419 and hardware of the computing device 109. The operating system 423 may also implement and/or enforce various security safeguards and mechanisms to prevent access to hardware or software resources by unprivileged or unauthorized users or processes 419.

The operating system 423 can also implement a virtual memory system that provides an abstract representation of the memory 409 available on the computing device 109, such as the RAM. Among the features provided by the virtual memory system are a per process 419 address space, which maps virtual addresses used by a process 419 to physical addresses of the memory 409. The processor's memory management unit (MMU) can translate these virtual addresses to physical addresses, when used. The operating system 423 can use the virtual memory system to present more memory 409 to individual processes 419 than is physically available.

A number of software components discussed can be stored in the memory of computing devices and are executable by the processor of the respective computing devices. In this respect, the term “executable” means a program file that is in a form that can ultimately be run by the processor. Examples of executable programs can be a compiled program that can be translated into machine code in a format that can be loaded into a random access portion of the memory and run by the processor, source code that can be expressed in proper format such as object code that is capable of being loaded into a random access portion of the memory and executed by the processor, or source code that can be interpreted by another executable program to generate instructions in a random access portion of the memory to be executed by the processor. An executable program can be stored in any portion or component of the memory, including random access memory (RAM), read-only memory (ROM), persistent memory, hard drive, solid-state drive, Universal Serial Bus (USB) flash drive, memory card, optical disc such as compact disc (CD) or digital versatile disc (DVD), floppy disk, magnetic tape, or other memory components.

Memory includes both volatile and nonvolatile memory and data storage components. Volatile components are those that do not retain data values upon loss of power. Nonvolatile components are those that retain data upon a loss of power. Thus, the memory can include random access memory (RAM), read-only memory (ROM), hard disk drives, solid-state drives, USB flash drives, memory cards accessed via a memory card reader, floppy disks accessed via an associated floppy disk drive, optical discs accessed via an optical disc drive, magnetic tapes accessed via an appropriate tape drive, or other memory components, or a combination of any two or more of these memory components. In addition, the RAM can include static random access memory (SRAM), dynamic random access memory (DRAM), or magnetic random access memory (MRAM) and other such devices. The ROM can include a programmable read-only memory (PROM), an erasable programmable read-only memory (EPROM), an electrically erasable programmable read-only memory (EEPROM), or other like memory device.

Although the applications and systems described herein can be embodied in software or code executed by general purpose hardware as discussed above, as an alternative the same can also be embodied in dedicated hardware or a combination of software/general purpose hardware and dedicated hardware. If embodied in dedicated hardware, each can be implemented as a circuit or state machine that employs any one of or a combination of a number of technologies. These technologies can include, but are not limited to, discrete logic circuits having logic gates for implementing various logic functions upon an application of one or more data signals, application specific integrated circuits (ASICs) having appropriate logic gates, graphics processing units (GPUs), field-programmable gate arrays (FPGAs), or other components, etc. Such technologies are generally well known by those skilled in the art and, consequently, are not described in detail herein.

Flowcharts may be used to describe the functionality and operation of an implementation of portions of the various embodiments of the present disclosure. If embodied in software, each block can represent a module, segment, or portion of code that includes program instructions to implement the specified logical function(s). The program instructions can be embodied in the form of source code that includes human-readable statements written in a programming language or machine code that includes numerical instructions recognizable by a suitable execution system such as a processor in a computer system. The machine code can be converted from the source code through various processes. For example, the machine code can be generated from the source code with a compiler prior to execution of the corresponding application. As another example, the machine code can be generated from the source code concurrently with execution with an interpreter. Other approaches can also be used. If embodied in hardware, each block can represent a circuit or a number of interconnected circuits to implement the specified logical function or functions.

Although flowcharts can show a specific order of execution, it is understood that the order of execution can differ from that which is depicted. For example, the order of execution of two or more blocks can be scrambled relative to the order shown. Also, two or more blocks shown in succession can be executed concurrently or with partial concurrence. Further, in some embodiments, one or more of the blocks shown in the flowcharts can be skipped or omitted. In addition, any number of counters, state variables, warning semaphores, or messages might be added to the logical flow described herein, for purposes of enhanced utility, accounting, performance measurement, or providing troubleshooting aids, etc. It is understood that all such variations are within the scope of the present disclosure.

Also, any logic or application described herein that includes software or code can be embodied in any non-transitory computer-readable medium for use by or in connection with an instruction execution system such as a processor in a computer system or other system. In this sense, the logic can include statements including instructions and declarations that can be fetched from the computer-readable medium and executed by the instruction execution system. In the context of the present disclosure, a “computer-readable medium” can be any medium that can contain, store, or maintain the logic or application described herein for use by or in connection with the instruction execution system. Moreover, a collection of distributed computer-readable media located across a plurality of computing devices (e.g., storage area networks or distributed or clustered filesystems or databases) may also be collectively considered as a single non-transitory computer-readable medium.

The computer-readable medium can include any one of many physical media such as magnetic, optical, or semiconductor media. More specific examples of a suitable computer-readable medium would include, but are not limited to, magnetic tapes, magnetic floppy diskettes, magnetic hard drives, memory cards, solid-state drives, USB flash drives, or optical discs. Also, the computer-readable medium can be a random access memory (RAM) including static random access memory (SRAM) and dynamic random access memory (DRAM), or magnetic random access memory (MRAM). In addition, the computer-readable medium can be a read-only memory (ROM), a programmable read-only memory (PROM), an erasable programmable read-only memory (EPROM), an electrically erasable programmable read-only memory (EEPROM), or other type of memory device.

Further, any logic or application described herein can be implemented and structured in a variety of ways. For example, one or more applications described can be implemented as modules or components of a single application. Further, one or more applications described herein can be executed in shared or separate computing devices or a combination thereof. For example, a plurality of the applications described herein can execute in the same computing device, or in multiple computing devices in the same computing environment.

Disjunctive language such as the phrase “at least one of X, Y, or Z,” unless specifically stated otherwise, is otherwise understood with the context as used in general to present that an item, term, etc., can be either X, Y, or Z, or any combination thereof (e.g., X, Y, or Z). Thus, such disjunctive language is not generally intended to, and should not, imply that certain embodiments require at least one of X, at least one of Y, or at least one of Z to each be present.

It should be noted that ratios, concentrations, amounts, and other numerical data may be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a concentration range of “about 0.1 percent to about 5 percent” should be interpreted to include not only the explicitly recited concentration of about 0.1 weight percent to about 5 weight percent but also include individual concentrations (e.g., 1 percent, 2 percent, 3 percent, and 4 percent) and the sub-ranges (e.g., 0.5 percent, 1.1 percent, 2.2 percent, 3.3 percent, and 4.4 percent) within the indicated range. The term “about” can include traditional rounding according to significant figures of the numerical value. In addition, the phrase “about ‘x’ to ‘y’” includes “about ‘x’ to about ‘y’”.

Many variations and modifications may be made to the above-described aspects. All such modifications and variations are intended to be included herein within the scope of this disclosure and protected by the following claims.

Therefore, the following is claimed:

1. A cantilever-based sensor device, comprising:
a flexible metal diaphragm that deforms in the presence of pressure against a first surface of the flexible metal diaphragm;
a housing that is at least partially enclosed using the flexible metal diaphragm over an opening of the housing;
a sensor component comprising a cantilever-based resonant sensor;
a column that connects between the flexible metal diaphragm and the resonant sensor, wherein the column connects to a second surface of the flexible metal diaphragm, wherein the second surface is on the opposite side of the first surface of the flexible metal diaphragm, wherein the column applies a tip force at a position of the cantilever-based resonant sensor in an instance in which the flexible metal diaphragm deforms, and the cantilever-based resonant sensor correlates to a pressure value based at least in part on a frequency shift in a resonant frequency of the cantilever based resonant sensor that results from the tip force.

2. The cantilever-based sensor device of claim 1, wherein the position is a distal end cantilever-based resonant sensor, wherein the column applies the tip force at the distal end of the cantilever-based resonant sensor in an instance in which the flexible metal diaphragm deforms.

3. The cantilever-based sensor device of claim 1, wherein the cantilever based resonant sensor comprises a resonator selected from the group consisting of: a tuning fork resonator, a surface acoustic wave (SAW) resonator, and a bulk acoustic resonator (BAW) resonator.

4. The cantilever-based sensor device of claim 1, wherein the column is attached to an extension component or is attached to the flexible metal diaphragm.

5. The cantilever-based sensor device of claim 1, further comprising:
an extension component that extends into an interior area at least partially enclosed or surrounded by the housing, wherein the cantilever-based resonant sensor is attached to the extension component and is in contact with or attached to the column.

6. The cantilever-based sensor device of claim 5, further comprising:
a spacing ring component that is sandwiched between the flexible metal diaphragm and the extension component, providing space between the extension component and the flexible metal diaphragm.

9. The cantilever-based sensor device of claim 5, further comprising a temperature-sensing component within the housing.

10. The cantilever-based sensor device of claim 9, wherein the temperature-sensing component is attached to the extension component.

11. The cantilever-based sensor device of claim 1, further comprising a vent in the housing.

12. The cantilever-based sensor device of claim 1, wherein the flexible metal diaphragm is a flat shape that fits over a plane formed by the opening of the housing.

13. The cantilever-based sensor device of claim 1, wherein the flexible metal diaphragm has a shape that includes a flexing portion and a sealing portion, wherein the flexing portion enables flexion while the sealing portion fits onto the housing.

14. The cantilever-based sensor device of claim 1, wherein the flexible metal diaphragm comprises stainless steel.

15. A system for measuring pressure, comprising
a cantilever-based sensor device within a structure of a processing system, wherein a first surface of a flexible metal diaphragm of the cantilever-based sensor device is in fluidic communication with a fluid in an inside region of the structure, wherein the fluid is a gas, a liquid, or a mixture of a gas and a liquid, wherein the flexible metal diaphragm is configured to deform to a degree based on a pressure against a first surface of the flexible metal diaphragm, wherein the pressure is from the fluid,
wherein the cantilever-based sensor device comprises: a sensor component comprising a cantilever-based resonant sensor; a column that connects between the flexible metal diaphragm and the resonant sensor, wherein the column connects to a second surface of the flexible metal diaphragm, wherein the second surface is on the opposite side of the first surface of the flexible metal diaphragm, wherein the column applies a tip force at a position of the cantilever-based resonant sensor in an instance in which the flexible metal diaphragm deforms based on the pressure against the first surface, wherein a frequency shift in a resonant frequency of the cantilever-based resonant sensor that results from the tip force produces a signal; and
a computing device is communicatively coupled with the cantilever-based sensor device, wherein the computing device receives the signal and is configured to compute a pressure value, wherein the computing device is communicatively coupled with the processing system, wherein the processing system is configured to process a pressure-based response based on the pressure value.

16. The system of claim 15, wherein the cantilever-based sensor device further comprises a temperature-sensing component, wherein the computing device receives a temperature signal from the cantilever-based sensor device and determines a temperature value, wherein the processing system is configured to process a temperature-based response based on the temperature value.

17. The system of claim 16, wherein the processing system is configured to process the temperature-based response to the temperature value and the pressure-based response to the pressure value to produce a parameter-based response.

18. A method for measuring one or more parameters in a process, comprising:
flowing a fluid in a structure in a processing system; and
measuring a pressure against a first surface of a flexible metal diaphragm of a cantilever-based sensor device within the structure of the processing system, wherein the flexible metal diaphragm is configured to deform to a degree based on a pressure against a first surface of the flexible metal diaphragm, wherein a first surface of a flexible metal diaphragm of the cantilever-based sensor device is in fluidic communication with a fluid in an inside region of the structure, wherein the fluid is a gas, a liquid, or a mixture of a gas and a liquid, wherein the pressure is from the fluid,
wherein the cantilever-based sensor device comprises: a sensor component comprising a cantilever-based resonant sensor; a column that connects between the flexible metal diaphragm and the resonant sensor, wherein the column connects to a second surface of the flexible metal diaphragm, wherein the second surface is on the opposite side of the first surface of the flexible metal diaphragm, wherein the column applies a tip force at a position of the cantilever-based resonant sensor in an instance in which the flexible metal diaphragm deforms based on the pressure against the first surface, wherein a frequency shift in a resonant frequency of the cantilever-based resonant sensor that results from the tip force produces a signal that correlates to a pressure value.

19. The method of claim 18, further comprising: measuring a temperature using a temperature-sensing component, wherein the cantilever-based sensor device comprises the temperature-sensing component.

20. The method of claim 19, further comprising: communicating the signal and the temperature to a computing device, wherein the computing device is configured to compute the pressure value, wherein the computing device is communicatively coupled with the processing system, wherein the processing system is configured to process a pressure-based response to the pressure value, wherein the processing system is configured to process a temperature-based response to the temperature value.
